(19) United States
(12) Patent Application Publication
(10) Pub. No.: US 2009/0295311 A1
(43) Pub. Date: Dec. 3, 2009

(54) Inspection lamp with elongated diffuser lens

(76) Inventors: John Duerr, Massapequa Park, NY (US); Gustavo Garcia, East Setauket, NY (US); Chih-Tsung Su, Hsin-Chaung City (CN)

Correspondence Address: DRINKER BIDDLE & REATH;ATTN: INTELLECTUAL PROPERTY GROUP, ONE LOGAN SQUARE, 18TH AND CHERRY STREETS, PHILADELPHIA, PA, 19103-6996, US

(21) Appl. No.: 12/454,983

(22) Filed: May 26, 2009

Related U.S. Application Data
(60) Provisional application No. 61/130,255, filed on May 28, 2008.

(51) Int. Cl. H05B 39/00; G02B 6/00; H01L 33/00

(52) U.S. Cl. 315/313; 362/551; 362/555

(57) ABSTRACT

An inspection lamp is disclosed that, in one embodiment, includes a transparent or translucent rod having two ends. Two light sources, one at each end of the rod, are arranged to emit light into the rod toward one another. The rod is located within a housing that has an opening. A reflector is located within the housing to direct the light in the rod toward the opening.

### RELATED APPLICATION

This application is related to and claims priority from U.S. Provisional Application No. 61/130,255, filed May 28, 2008, the disclosure of which is incorporated herein by reference in its entirety.

### TECHNICAL FIELD

The application relates to inspection lamps, and especially to an inspection lamp for exciting fluorescent dyes.

### BACKGROUND

Fluorescence is a phenomenon in which a substance absorbs light, and almost immediately re-radiates light of a longer wavelength. Fluorescent dyes have been created for use in detecting leaks from fluid containing systems. In use, a fluorescent dye is included in the fluid within the system. A region outside of the system, such as where a leak is suspected, is illuminated with light that has a wavelength that will excite the fluorescent dye. The area being illuminated is inspected for emission from the fluorescent dye. Fluorescent dyes used for this purpose are usually excited by light in the blue to ultraviolet wavelength range, and emit visible light in the green to yellow wavelength range.

With the availability of blue LEDs of reasonable brightness and efficiency, LED inspection lamps have been proposed for fluorescence leak detection. Many existing LED lamps are either of the penlight configuration, such as U.S. Pat. No. 6,491,408. These lamps provide light essentially only from one point, and cannot effectively illuminate large areas. Long LED inspection lamps have been proposed, but those lamps typically use an array of LEDs along the length of the lamp, which increases the cost and complexity of the lamp undesirably.

There is therefore still a need for an elongated LED inspection lamp that is simple and economical, and that emits light fairly evenly along its length on only one side.

### SUMMARY OF THE INVENTION

According to one embodiment of the invention, there is provided an inspection lamp comprising a rod of light-dispersing material, an LED at each end of the rod positioned to shine light into the rod, and a shield along one side of the rod.

The LED at each end of the lamp may be a single LED, or there may be a compact cluster of LEDs. A single powerful LED is preferred for simplicity and robustness. The shield may be, or may include, a reflector. In a preferred arrangement, a reflector is applied to or positioned close to the light-dispersing rod, and a robust outer shield is positioned behind the reflector. Power wires may be positioned between the reflector and the outer shield, allowing the LEDs at both ends to be supplied by a power source at one end, such as batteries in a handle. Alternatively, if the shield is of metal or other electrically conducting material, it may provide one side of an electrical circuit. The outer shield may also provide structural support for the rod and for an end-cap at the end further from the handle.

Additional components, such as switches, current or voltage limiting, regulating, and/or boosting circuits, may be provided as appropriate. Also, while the lamp is shown with a single color LED, it is contemplated that multiple LEDs would be mounted to each end and could be of different colors to provide different light illumination depending on the need.

### BRIEF DESCRIPTION OF THE DRAWINGS

The above and other aspects, features and advantages of the present invention will be more apparent from the following more particular description thereof, presented in conjunction with the following drawings wherein:

FIG. 1 is a longitudinal sectional view of an inspection lamp.

FIG. 2 is a cross section of the lamp shown in FIG. 1, taken along the line 2-2 in FIG. 1.

FIG. 3 is a schematic of the lamp of FIG. 1 with replaceable LED modules.

### DETAILED DESCRIPTION OF THE PREFERRED EMBODIMENTS

Referring to the accompanying drawings, one example of an inspection lamp according to an embodiment of the present invention is indicated generally by the reference number 10.

The lamp 10 includes a transparent or semi-transparent (translucent) rod 12, mounted within a generally tubular housing 14. At least one and more preferably at least two light emitting diodes (LEDs) 16 are mounted within the housing 14, one at each end of the rod 12, and positioned to direct their light into the rod 12. It is also contemplated that there may be a plurality of LEDS clustered together on either side of the rod.

The LEDs 16 are chosen to have a spectral output optimized for an intended use of the lamp 10. For example, where the lamp 10 is intended as an inspection lamp for fluorescence leak detection, the LEDs 16 may be selected to emit light strongly at the excitation frequency of a fluorescent dye, or in a range including the excitation frequencies of a range of fluorescent dyes, typically in the blue, violet, near ultraviolet and ultraviolet range, such as UV-A, UV-B or UV-C ranges, of the spectrum. White or broad-spectrum LEDs may be used, the use of LEDs that emit light significantly at the wavelengths (typically yellow or green) of fluorescence of the dyes used may make the fluorescence harder to see. Thus, broad range light emittance is not preferred.

The rod 12 is preferably generally cylindrical with a circular cross-section, and may be of quartz, glass, acrylic or other suitable material, depending on the spectral output from the LEDs 16. The material of the rod 12 is preferably chosen to act as a waveguide and have a low absorption for the desired light from the LEDs 16 but, as is explained below, may be chosen to diffuse or scatter the light to a significant extent. The connection between the LEDs 16 and the rod 12 may be designed in accordance with established optical principles and practices to ensure efficient light transfer from the LEDs to the rod. In one embodiment, the LEDs are placed at either end of the rod and oriented so as to emit light into the rod end.

The tubular housing 14 is arranged to cover both ends of the transparent rod 12 and to cover and protect the LEDs 16. The housing 14 includes an opening 18 formed in the housing between its ends and extending along one side of the rod 12. The opening is preferably extends approximately half the circumference of the housing and almost the whole length of the rod. For robustness and ease of construction, the housing 14 may be made of metal or plastic. Opposite the opening 18, a reflector 20 is provided between the rod 12 and the housing 14. The reflector 20 may be in the form of a reflective coating, such as a white coating, on the rod 12 or housing 14, or may be a sheet of white, or white-coated, material, such as plastic or metal partly surrounding the rod 12. Where only a narrow spectral band of light from the LEDs 16 is of use, the reflector 20 may be of a color that absorbs light of other wavelengths. However, unless it is desired actively to suppress unwanted wavelengths, a white or mirrored material or coating is usually simpler and more economical. Also, if high-power LEDs are used, the incorporation of a reflective coating rather than an absorptive material will heat up less.

A guard over the opening 18 is usually not necessary, because the rod 12, being solid plastic, is typically quite robust and durable, and minor surface scratches typically do not materially impair the operation of the lamp 10. However, it is contemplated that a sliding or hinged cover could be added to cover the opening when the lamp is not in use.

The housing 14 extends beyond the rod 12 at one end, forming a handle 22 for the lamp 10. The handle may be formed integral with the light portion of the housing, or may be separately attached to the light portion, such as with threads. A power source in the form of batteries 24 is provided within the handle 22. A tubular handle 22 provides a suitable space for a plurality of conventional cylindrical dry cells 24 placed end to end. Other power sources, such as a rechargeable battery pack, or a power cord connected to an external power supply, may be used instead. Power may be transmitted from the batteries 24 to the LEDs 16 by wires 26 within the housing 14. As shown in the drawings, the housing 12 is of metal, and preferably serves as an electrical ground conductor. As such, the only separate wire 26 needed is a single insulated wire from a contact point between the batteries 24 and the nearer LED 16 to the further LED 16. Alternatively, a greater part of the electrical conduction may be by separate wires 26.

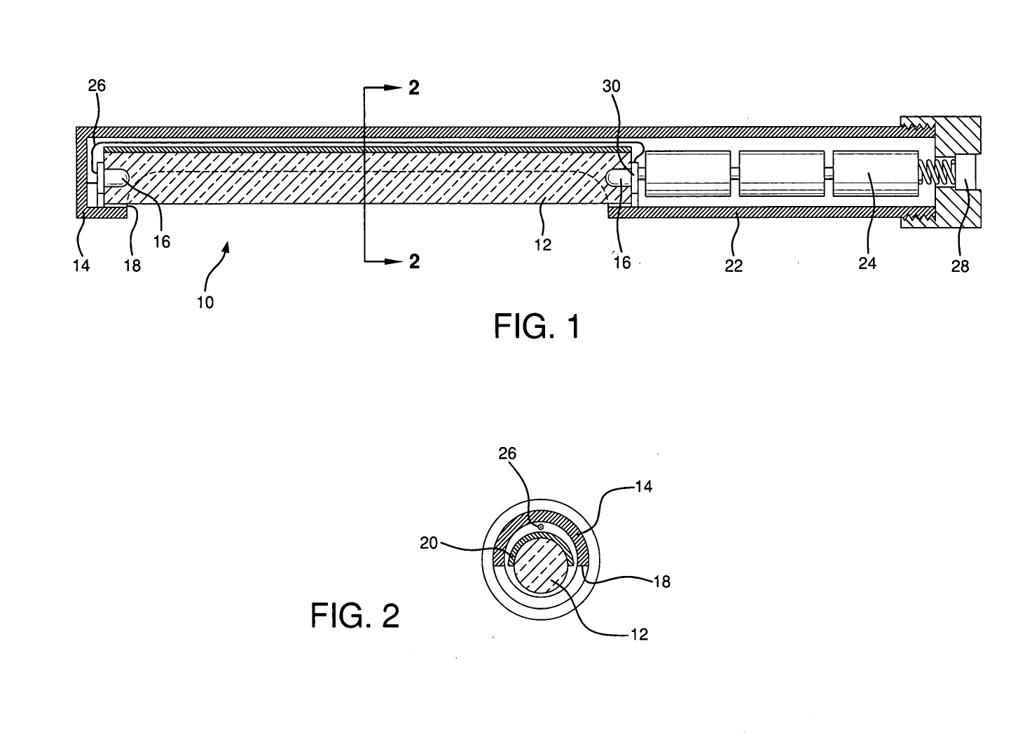

An on/off switch 28, which may be conventional, is provided. In one preferred embodiment, in order to provide a smooth handle without any obtrusions, the switch 28 is formed in the end of the handle as shown in FIG. 1. Other circuitry 30 (not shown in detail) may be provided as desired. For example, many commonly available high-brightness LEDs have a voltage drop of around 3.5 volts. When such LEDs are powered by conventional dry cells with a nominal voltage of 1.5 volts, two cells in series do not provide sufficient voltage to produce the full light output of the LEDs, while three cells in series provide an excessive voltage that can shorten the life of the LEDs and waste power. Therefore, the circuitry 30 may include current or voltage limiting, regulating, and/or boosting circuitry as appropriate depending on the specific choice of power source and LEDs. Alternatively, in the interests of simplicity and robustness, the circuitry 30 may be omitted, and any consequent reduction in performance may be accepted.

In use, when the switch 28 is turned on, the batteries 24 supply power to the LEDs 16, which shine into the ends of the rod 12. Scattering of light by the material of the rod 12, combined with reflection from the reflector 20, directs the light to one side, corresponding with the opening 18 in the housing. The opening in the housing combined with reflector provides a a wide dispersing of the light. In one embodiment of the invention, a lamp that included a ten inch long exposed rod with an approximately ½ inch diameter was positioned 6 inches above the ground. The emitted beam illuminated an 11 inch wide and 24 inch long area, with a high concentration of light in the center, This is due to the partial masking of light from the rod 12 by the housing 14, combined with focusing of light from the reflector 20 by the curved surface of the rod, which produces a surprisingly concentrated output, with almost all the light being concentrated in a rectangular beam only about 90° wide.

Although it might be expected that the light intensity would diminish away from the LEDs 16 towards the middle of the rod 12, the injection of light at both ends of the rod, combined with a certain amount of redistribution by multiple scattering, can produce a surprisingly even distribution, with no noticeable unevenness or hot spot along the length of the rod 12.

As an example of suitable dimensions, and inspection lamp is about 18.5″ (47 cm) in overall length, with a rod having a length of about 12″ (30 cm) long and about 0.55″ (14 mm) in diameter. The opening in the housing exposes about 10″ (25 cm) of rod's length. The handle may be about 1.2″ (3 cm) in diameter for comfort in use and to accommodate standard “C” cells, which are about 1″ (2.5 cm) in diameter.

It is contemplated that the inspection lamp may include more than one LED at each end. The LEDs at each end could be wired, if desired, so that they illuminate together to provide high intensity or less than all of the LEDs illuminate if a lower intensity is desired

Furthermore, the LEDs need not be the same color. For example, multiple LEDs can be included at each end such that the lamp can be switched between different wavelengths of illumination. For example, each end can include at least one white LED, one UV LED, one blue LED, one green LED one amber LED and one red LED (or any number or combination of these LEDs.) The switch 28 on the housing 14 can be configured to allow the user to select the illumination desired or the circuitry can be arranged to cycle through all the different groups of LEDs upon depressing of the switch 28. Thus, the lamp could emit some or all of these wavelengths. Also, combinations of any of these LEDs can also be illuminated. For example, instead of including an amber LED, the green and the red LED can be illuminated simultaneously to produce a perceived amber light. Also, red, blue and green can be illuminated simultaneously to produce sufficient visible light to eliminate the need for a separate white LED.

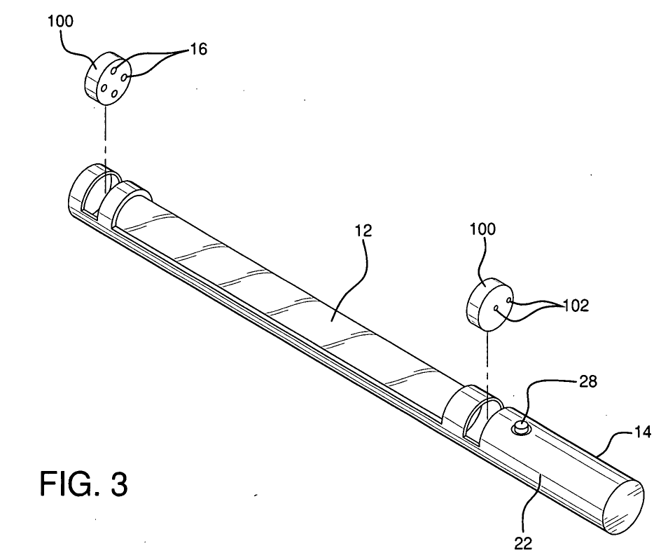

It is contemplated that the LEDs can be formed on a modular attachment 100 that is removably attached to the lamp, thus permitting the desired arrangement of LEDs 16 (e.g., desired color) to be attached to the lamp. The LED module 100 can be inserted into openings the housing as shown in FIG. 3. The modules would include contacts 102 that connect with circuitry inside the housing 14 to permit the LEDs to be powered.

While the housing is shown as a straight cylinder, it is also contemplated that the housing and rod may have a different shape, such as curved, so as to permit certain desired illumination. For example, for inspection of pipes, a curved rod and housing may be desirable to provide consistent and directed illumination. It is also contemplated that the lamp can be used for curing, such as curing adhesives or composite materials.

Although specific embodiments have been described, the skilled reader will understand how various modifications may be made within the scope of the present invention, which is defined by the attached claims.

What is claimed is:

1. An inspection lamp, comprising:
a housing having an elongated portion with an opening formed in one side of the elongated portion of the housing;
a transparent rod having two ends and mounted within the elongated portion of the housing, at least a portion of the rod exposed in the opening;
at least two light sources mounted within the housing, one located at each end of the rod and positioned so as to emit light into an end of the rod; and
a reflector located within the housing and adapted to reflect light passing through the rod toward the opening.

2. The inspection lamp of claim 1, wherein the rod is straight and of substantially circular cross-section.

3. The inspection lamp of claim 1, wherein the light sources comprise LEDs.

4. The inspection lamp of claim 3, wherein the light sources comprise blue LEDs.

5. The inspection lamp of claim 3, wherein each of the light sources comprises a single LED.

6. The inspection lamp of claim 1, wherein reflector is a coating on a surface of the rod located on the opposite side of the rod from the opening.

7. The inspection lamp of claim 1, wherein the rod is of circular cross-section and the housing permits light to emerge over substantially half the circumference thereof.

8. The inspection lamp of claim 1 wherein the light sources are LEDs and wherein there are multiple LEDs on either end of the rod.

9. The inspection lamp of claim 8 wherein the LEDs on an end of the rod emit different wavelengths of light.

10. The inspection lamp of claim 9 wherein the LEDs are connected to a switch for controlling the color of the light emitted by the lamp.

11. The inspection lamp of claim 1 wherein the light sources are part of a modular unit that can be removably attached to the lamp.

12. The inspection lamp of claim 11 wherein the lamp is part of a kit that includes at least sets of two modular units, wherein one set of modular units includes LEDs that emit light at a first wavelength and the other set of modular units includes LEDs that emit light at a second wavelength that is different from the first wavelength.

13. The inspection lamp of claim 1, wherein at least a portion of the length of the rod is non-linear in shape.
